(19) United States
(12) Patent Application Publication
(10) Pub. No.: US 2025/0311548 A1
(43) Pub. Date: Oct. 2, 2025

(54) DISPLAY APPARATUS AND METHOD OF MANUFACTURING THE SAME

(71) Applicant: SAMSUNG DISPLAY CO., LTD., Yongin-si (KR)

(72) Inventors: Taesang KIM, Yongin-si (KR); Hyoungdo KIM, Yongin-si (KR); Joonseok PARK, Yongin-si (KR); Hyelim CHOI, Yongin-si (KR)

(21) Appl. No.: 19/004,784

(22) Filed: Dec. 30, 2024

(30) Foreign Application Priority Data
Mar. 27, 2024 (KR) 10-2024-0042007

(51) Int. Cl. H10K 59/121; H10D 86/40; H10D 86/60; H10K 59/12

(52) U.S. Cl. CPC H10K 59/1213; H10D 86/423; H10D 86/443; H10D 86/60; H10K 59/1201

(57) ABSTRACT

A display apparatus includes a pixel circuit on a substrate. The pixel circuit includes first and second transistors. A display element is electrically connected to the pixel circuit. The first transistor includes a first semiconductor layer disposed on the substrate. The first semiconductor layer includes a 1-1 semiconductor layer, a 1-2 semiconductor layer, and a 1-3 semiconductor layer disposed between the 1-1 semiconductor layer and the 1-2 semiconductor layer. The 1-1 semiconductor layer and the 1-2 semiconductor layer include a same material as each other and the 1-3 semiconductor layer includes a material different from the material of the 1-1 and 1-2 semiconductor layers. A first gate electrode is disposed on the first semiconductor layer and overlaps the 1-3 semiconductor layer. A first connection electrode is disposed on the first gate electrode. The first connection electrode is electrically connected to the 1-1 semiconductor layer or the 1-2 semiconductor layer.

### CROSS-REFERENCE TO RELATED APPLICATION

This application claims priority under 35 U.S.C. § 119 to Korean Patent Application No. 10-2024-0042007, filed on Mar. 27, 2024 in the Korean Intellectual Property Office, the disclosure of which is incorporated by reference in its entirety herein.

### 1. TECHNICAL FIELD

One or more embodiments relate to a display apparatus and a method of manufacturing the same, and more particularly, to a display apparatus capable of reducing the risk of defects occurring during a manufacturing process and a method of manufacturing the display apparatus.

### 2. DISCUSSION OF RELATED ART

A display apparatus includes a display element and a pixel circuit electrically connected to the display element. The pixel circuit includes a driving transistor for controlling an amount of current flowing to the display element. The pixel circuit also includes a switching transistor for performing a switching function. The switching transistor should be able to be relatively quickly turned on or off to perform a switching function. Accordingly, a semiconductor layer of the switching transistor may have a higher charge mobility than a charge mobility of a semiconductor layer of the driving transistor.

However, a conventional display apparatus may have defects due to hydrogen penetrating into a semiconductor layer during a process of manufacturing a display apparatus.

### SUMMARY

One or more embodiments of the present disclosure include a display apparatus capable of reducing the risk of defects occurring during a manufacturing process and a method of manufacturing the display apparatus.

Additional aspects will be set forth in part in the description which follows and, in part, will be apparent from the description, or may be learned by practice of the described embodiments.

According to an embodiment of the present disclosure, a display apparatus includes a pixel circuit disposed on a substrate. The pixel circuit includes first and second transistors. A display element is electrically connected to the pixel circuit. The first transistor includes a first semiconductor layer disposed on the substrate. The first semiconductor layer includes a 1-1 semiconductor layer, a 1-2 semiconductor layer, and a 1-3 semiconductor layer disposed between the 1-1 semiconductor layer and the 1-2 semiconductor layer. The 1-1 semiconductor layer and the 1-2 semiconductor layer include a same material as each other and the 1-3 semiconductor layer includes a material different from the material of the 1-1 and 1-2 semiconductor layers. A first gate electrode is disposed on the first semiconductor layer and overlaps the 1-3 semiconductor layer. A first connection electrode is disposed on the first gate electrode. The first connection electrode is electrically connected to the 1-1 semiconductor layer or the 1-2 semiconductor layer.

In an embodiment, the second transistor may include a second semiconductor layer including a 2-1 semiconductor layer disposed on the substrate and a 2-2semiconductor layer disposed on the 2-1 semiconductor layer. The 2-2 semiconductor layer includes a material different from a material included in the 2-1 semiconductor layer. A second gate electrode is disposed on the second semiconductor layer. The second gate electrode overlaps the 2-2 semiconductor layer. A second connection electrode is disposed on the second gate electrode. The second connection electrode is electrically connected to the 2-1 semiconductor layer.

In an embodiment, the display apparatus may further include a buffer layer disposed between the substrate and the first semiconductor layer and between the substrate and the second semiconductor layer. A first inorganic insulating layer is disposed between the first semiconductor layer and the first gate electrode and between the second semiconductor layer and the second gate electrode. A second inorganic insulating layer is disposed between the first gate electrode and the first connection electrode and between the second gate electrode and the second connection electrode.

In an embodiment, the 1-3 semiconductor layer may directly contact the buffer layer.

In an embodiment, a first portion of the 1-3 semiconductor layer may cover a portion of the 1-1 semiconductor layer. A second portion of the 1-3 semiconductor layer may cover a portion of the 1-2 semiconductor layer.

In an embodiment, the 1-1 semiconductor layer may be electrically connected to the 1-2 semiconductor layer by the 1-3 semiconductor layer.

In an embodiment, the 1-3 semiconductor layer may be electrically connected to the first connection electrode by the 1-1 semiconductor layer or the 1-2 semiconductor layer.

In an embodiment, the 2-1 semiconductor layer may be disposed between the 2-2 semiconductor layer and the buffer layer.

In an embodiment, the 2-2 semiconductor layer may be electrically connected to the second connection electrode by the 2-1 semiconductor layer.

In an embodiment, the first transistor may be electrically connected to the display element.

In an embodiment, the display element may include a pixel electrode, a counter electrode, and an emission layer disposed between the pixel electrode and the counter electrode. The first connection electrode is electrically connected to the pixel electrode.

In an embodiment, the material included in the 1-1 semiconductor layer and the 1-2 semiconductor layer may have a higher charge mobility than a charge mobility of the material included in the 1-3 semiconductor layer.

In an embodiment, the material included in the 2-1 semiconductor layer may have a higher charge mobility than a charge mobility of the material included in the 2-2 semiconductor layer.

In an embodiment, the material included in the 1-1 semiconductor layer and the 1-2 semiconductor layer is a same material as the material included in the 2-1 semiconductor layer. The material included in the 1-3 semiconductor layer is a same material as the material included in the 2-2 semiconductor layer.

In an embodiment, the material included in the 1-1 semiconductor layer, the 1-2 semiconductor layer, and the 2-1 semiconductor layer may include indium tin oxide, and the material included in the 1-3 semiconductor layer and the 2-2 semiconductor layer may include indium gallium zinc oxide.

According to an embodiment of the present disclosure, a method of manufacturing a display apparatus includes forming a 1-1 semiconductor layer and a 1-2 semiconductor layer that are spaced apart from each other on a buffer layer disposed on a substrate. The 1-1 semiconductor layer and the 1-2 semiconductor layer include a same material as each other. A 1-3 semiconductor layer is formed between the 1-1semiconductor layer and the 1-2 semiconductor layer. The 1-3 semiconductor layer includes a material different from the material of the 1-1 semiconductor layer and the 1-2 semiconductor layer. A first inorganic insulating layer is formed on the 1-1 semiconductor layer, the 1-2 semiconductor layer, and the 1-3 semiconductor layer. A first gate electrode is formed on the first inorganic insulating layer, the first gate electrode overlapping the 1-3 semiconductor layer. A second inorganic insulating layer is formed on the first gate electrode. A first connection electrode is formed that is electrically connected to the 1-1 semiconductor layer or the 1-2 semiconductor layer on the second inorganic insulating layer.

In an embodiment, the forming of the 1-3 semiconductor layer may include forming the 1-3 semiconductor layer in direct contact with the buffer layer.

In an embodiment, the forming of the 1-3 semiconductor layer may include forming the 1-3 semiconductor layer so that a first portion of the 1-3 semiconductor layer covers a portion of the 1-1 semiconductor layer and a second portion of the 1-3 semiconductor layer covers a portion of the 1-2 semiconductor layer.

In an embodiment, the material included in the 1-1 semiconductor layer and the 1-2 semiconductor layer may have a higher charge mobility than a charge mobility of the material included in the 1-3 semiconductor layer.

In an embodiment, the forming of the 1-1 semiconductor layer and the 1-2 semiconductor layer may further include forming a 2-1 semiconductor layer that is spaced apart from the 1-1 semiconductor layer and the 1-2 semiconductor layer on the buffer layer. The forming of the 1-3 semiconductor layer may further include forming a 2-2 semiconductor layer on the 2-1 semiconductor layer. The forming of the first gate electrode may further include forming a second gate electrode on the first inorganic insulating layer. The second gate electrode overlaps the 2-2 semiconductor layer. The forming of the first connection electrode may further include forming a second connection electrode electrically connected to the 2-1 semiconductor layer on the second inorganic insulating layer.

In an embodiment, the forming of the 2-2 semiconductor layer may include forming the 2-2 semiconductor layer to cover a portion of the 2-1 semiconductor layer.

In an embodiment, the 2-1 semiconductor layer may include a material having a higher charge mobility than a charge mobility of a material included in the 2-2 semiconductor layer.

According to an embodiment of the present disclosure, a display apparatus includes a pixel circuit disposed on a substrate. The pixel circuit comprises a driving transistor and a switching transistor. A display element is electrically connected to the pixel circuit. The driving transistor comprises a first semiconductor layer disposed on the substrate. The first semiconductor layer comprising a 1-1 semiconductor layer and a 1-2 semiconductor layer spaced apart from each other in a horizontal direction parallel to an upper surface of the substrate. A 1-3 semiconductor layer is disposed between the 1-1 semiconductor layer and the 1-2 semiconductor layer in the horizontal direction. The 1-3 semiconductor layer includes a first lateral side directly contacting the 1-1 semiconductor layer, an opposite second lateral side directly contacting the 1-2 semiconductor layer and a central portion that does not directly contact either of the 1-1 semiconductor layer and the 1-2 semiconductor layer. The 1-1 semiconductor layer and the 1-2 semiconductor layer include a same material as each other and the 1-3 semiconductor layer includes a material different from the material included in the 1-1 semiconductor layer and the 1-2 semiconductor layer.

In an embodiment, the switching transistor includes a second semiconductor layer comprising a 2-1 semiconductor layer disposed on the substrate. A 2-2 semiconductor layer is disposed directly on an upper surface of the 2-1 semiconductor layer. The 2-2 semiconductor layer has a smaller area than the 2-1 semiconductor layer and overlaps a portion of the 2-1 semiconductor layer. The 2-2 semiconductor layer includes a material different from a material included in the 2-1 semiconductor layer.

In an embodiment, a material included in the 1-1 semiconductor layer, the 1-2 semiconductor layer and the 2-1 semiconductor layer is the same as each other. A material included in the 1-3 semiconductor layer and the 2-2 semiconductor layer is the same as each other. The material included in the 1-1 semiconductor layer, the 1-2 semiconductor layer and the 2-1 semiconductor layer has a higher charge mobility than a charge mobility of the material included in the 1-3 semiconductor layer and the 2-2 semiconductor layer.

Other aspects, features, and advantages of the disclosure will become more apparent from the detailed description, the claims, and the drawings.

### BRIEF DESCRIPTION OF THE DRAWINGS

The above and other aspects, features, and advantages of certain non-limiting embodiments will be more apparent from the following description taken in conjunction with the accompanying drawings, in which:

FIG. 1 is a plan view schematically illustrating a display apparatus, according to an embodiment of the present disclosure;

FIG. 2 is an equivalent circuit diagram illustrating one pixel included in a display apparatus, according to an embodiment of the present disclosure;

FIG. 3 is a cross-sectional view taken along line I-I′ of the display apparatus of FIG. 1 according to an embodiment of the present disclosure; and

FIGS. 4 to 9 are cross-sectional views schematically illustrating part of a process of manufacturing the display apparatus of FIG. 3 according to embodiments of the present disclosure.

### DETAILED DESCRIPTION OF EMBODIMENTS

Reference will now be made in detail to non-limiting embodiments, examples of which are illustrated in the accompanying drawings, wherein like reference numerals refer to like elements throughout. In this regard, the described embodiments may have different forms and should not be construed as being limited to the descriptions set forth herein. Accordingly, non-limiting embodiments are merely described below, by referring to the figures, to explain aspects of the present disclosure. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain non-limiting embodiments will be illustrated in the drawings and described in the detailed description. Effects and features of the present disclosure, and methods for achieving them will be clarified with reference to embodiments described below in detail with reference to the drawings. However, embodiments of the present disclosure are not limited to the described embodiments and may be embodied in various forms.

While such terms as “first,” “second,” etc., may be used to describe various components, such components are not be limited to the above terms. The above terms are used only to distinguish one component from another.

The singular forms “a,” “an,” and “the” as used herein are intended to include the plural forms as well unless the context clearly indicates differently.

It will be further understood that the terms “comprises” or “comprising” used herein specify the presence of stated features or components, but do not preclude the presence or addition of one or more other features or components.

“A and/or B” is used herein to select only A, select only B, or select both A and B. “At least one of A and B” is used to select only A, select only B, or select both A and B.

It will be understood that when a component, such as a layer, a film, a region, or a plate, is referred to as being “on” another component, the component may be directly on the other component or intervening components may be present therebetween. When a component, such as a layer, a film, a region, or a plate, is referred to as being “directly on” another component, no intervening components may be present therebetween.

In the specification, it will be understood that when a layer, a region, or a component is referred to as being “connected” to another layer, region, or component, it may be “directly connected” to the other layer, region, or component and/or may be “indirectly connected” to the other layer, region, or component with other layers, regions, or components interposed therebetween. For example, when a layer, a region, or a component is referred to as being “electrically connected,” it may be directly electrically connected, and/or may be indirectly electrically connected with intervening layers, regions, or components therebetween.

In the specification, the x-axis, the y-axis and the z-axis are not necessarily limited to three axes of the rectangular coordinate system, and may be interpreted in a broader sense. For example, the x-axis, the y-axis, and the z-axis may be perpendicular to one another or may represent different directions that cross each other but are not perpendicular to one another.

In the specification, when a certain embodiment may be implemented differently, a specific process order may be different from the described order. For example, two consecutively described processes may be performed substantially at the same time or may be performed in an order opposite to the described order.

Hereinafter, embodiments will be described in detail with reference to the accompanying drawings, wherein the same or corresponding elements are denoted by the same reference numerals throughout and a repeated description thereof is omitted. Sizes of components in the drawings may be exaggerated or contracted for convenience of explanation. For example, since sizes and thicknesses of components in the drawings may be arbitrarily illustrated for convenience of explanation, embodiments of the present disclosure are not necessarily limited thereto.

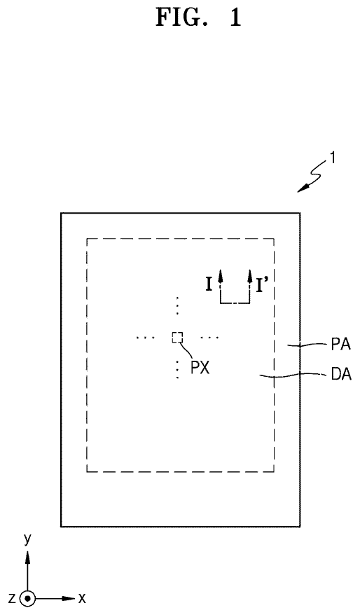

FIG. 1 is a plan view schematically illustrating a display apparatus 1, according to an embodiment. As shown in FIG. 1, the display apparatus 1 may include a display area DA where a plurality of pixels PX are located and a peripheral area PA located outside the display area DA (e.g., in the x and/or y directions). For example, in an embodiment the peripheral area PA may entirely surround the display area DA (e.g., in the x and/or y directions).

Each pixel PX of the display apparatus 1 is an area where light of a certain color may be emitted, and the display apparatus 1 may provide an image by using light emitted from the pixels PX. For example, in an embodiment each pixel PX may emit red light, green light, or blue light. However, embodiments of the present disclosure are not necessarily limited thereto and the colors of the light emitted by each pixel PX may vary. The display area DA may have any of polygonal shapes including a quadrangular shape as shown in FIG. 1. For example, the display area DA may have a rectangular shape in which a horizontal length is less than a vertical length, a rectangular shape in which a horizontal length is greater than a vertical length, or a square shape. Alternatively, the display area DA may have any of various shapes such as an elliptical shape, a circular shape, etc.

The peripheral area PA may be a non-display area where no pixels PX are located. A driver or the like for applying an electrical signal or power to the pixels PX may be located in the peripheral area PA. In an embodiment, a plurality of pads to which an electronic element or a printed circuit board may be electrically connected may be located in the peripheral area PA. The pads may be located in the peripheral area PA to be spaced apart from each other and may each be electrically connected to a printed circuit board or an integrated circuit device.

Although an organic light-emitting display apparatus is described as the display apparatus 1 according to an embodiment, the display apparatus 1 of the disclosure is not necessarily limited thereto. For example, in an embodiment, the display apparatus 1 of the disclosure may be a display apparatus such as an inorganic light-emitting display apparatus (e.g., an inorganic electroluminescent (EL) display apparatus) or a quantum dot light-emitting display apparatus. For example, in an embodiment an emission layer of a display element included in the display apparatus 1 may include an organic material or an inorganic material. Also, the display apparatus 1 may include an emission layer and a quantum dot layer located in a path of light emitted from the emission layer.

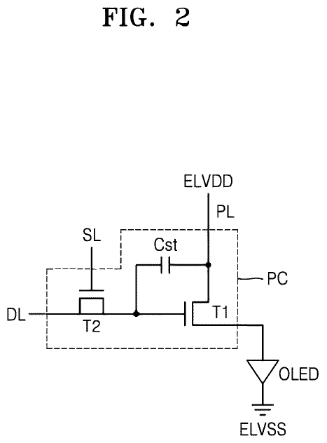

FIG. 2 is an equivalent circuit diagram illustrating one pixel PX included in the display apparatus 1, according to an embodiment of the present disclosure. As shown in FIG. 2, one pixel PX may correspond to one display element, and each display element may be electrically connected to a pixel circuit PC. In FIG. 2, an organic light-emitting diode OLED is illustrated as a display element for convenience of explanation.

In an embodiment, the pixel circuit PC may include a first transistor T1, a second transistor T2, and a storage capacitor Cst. The second transistor T2 may be a switching transistor that is connected to a scan line SL and a data line DL, and may transmit a data voltage input from the data line DL to the first transistor T1 according to a switching voltage input from the scan line SL. The storage capacitor Cst may be connected to the second transistor T2 and a driving voltage line PL, and may store a voltage corresponding to a difference between a voltage received from the second transistor T2 and a first power supply voltage ELVDD supplied to a driving voltage line PL.

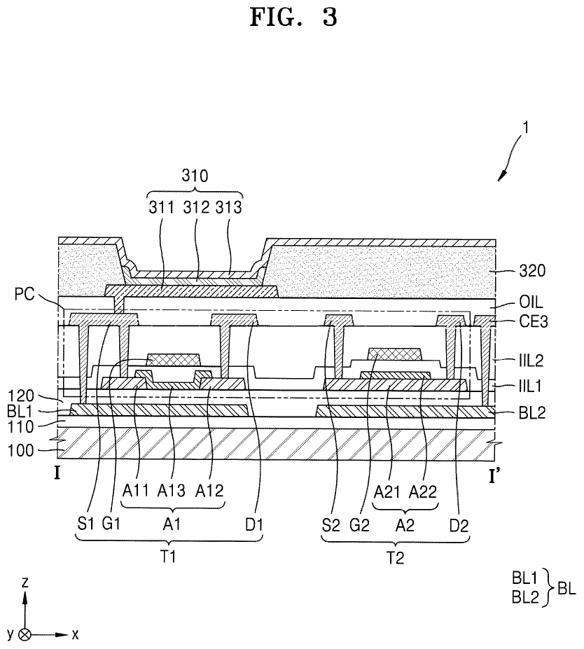

In an embodiment, the first transistor T1 may be a driving transistor that is connected to the driving voltage line PL and the storage capacitor Cst, and may control driving current flowing from the driving voltage line PL to the organic light-emitting diode OLED in response to a value of the voltage stored in the storage capacitor Cst. The organic light-emitting diode OLED may emit light having a certain luminance due to the driving current. A counter electrode 313 (see FIG. 3) of the organic light-emitting diode OLED may receive a second power supply voltage ELVSS.

Although the pixel circuit PC includes two transistors and one storage capacitor in an embodiment shown in FIG. 2, embodiments of the present disclosure are not necessarily limited thereto. For example, the number of transistors or the number of storage capacitors may be changed in various ways according to a design of the pixel circuit PC.

FIG. 3 is a cross-sectional view taken along line I-l′ of the display apparatus 1 of FIG. 1 according to an embodiment of the present disclosure.

As shown in FIG. 3, the display apparatus 1 includes a substrate 100, the pixel circuit PC and a display element 310 electrically connected to the pixel circuit PC located on the substrate 100. In an embodiment shown in FIG. 3, an organic light-emitting diode is the display element 310 disposed on the substrate 100. However, embodiments of the present disclosure are not necessarily limited thereto. When the display element 310 is electrically connected to the pixel circuit PC, it may mean that a pixel electrode 311 included in the display element 310 is electrically connected to thin- film transistors of the pixel circuit PC.

In an embodiment, the substrate 100 may include glass, a metal, or a polymer resin. The substrate 100 may be flexible or bendable. In an embodiment in which the substrate 100 is flexible or bendable, the substrate 100 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate.

A barrier layer 110 may be located on the substrate 100 (e.g., disposed directly thereon in the z direction). In an embodiment, the barrier layer 110 may be formed on (e.g., disposed on) an entire surface of the substrate 100 to cover the substrate 100. The barrier layer 110 may include an inorganic material. For example, in an embodiment the barrier layer 110 may include an inorganic insulating material such as silicon oxide (SiO_{X}), silicon nitride (SiN_{X}), or silicon oxynitride (SiO_{X}N_{Y}) and may have a single or multi-layer structure including the above material.

A shielding layer BL may be located on the barrier layer 110 (e.g., disposed directly thereon in the z direction). In an embodiment, the shielding layer BL may include a first shielding layer BL1 and a second shielding layer BL2. The first shielding layer BL1 may overlap the first transistor T1 (e.g., in the z direction), and the second shielding layer BL2 may overlap the second transistor T2 (e.g., in the z direction). The shielding layer BL may function as a lower protective metal that protects a layer overlapping the shielding layer BL. In an embodiment, a constant voltage or signal may be applied to the first shielding layer BL1 and/or the second shielding layer BL2. The first shielding layer BL1 and/or the second shielding layer BL2 may more easily supply charges to a back channel portion of the pixel circuit PC. In an embodiment, the shielding layer BL may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu). The shielding layer BL may have a single or multi-layer structure including the above material.

A buffer layer 120 may be located on (e.g., disposed directly thereon) the shielding layer BL. For example, in an embodiment the buffer layer 120 may be formed over the entire surface of the substrate 100 to cover the shielding layer BL. The buffer layer 120 may increase smoothness of a top surface of the substrate 100 or may prevent or minimize penetration of impurities from the substrate 100 into semiconductor layers of transistors. The buffer layer 120 may include an inorganic material. For example, in an embodiment the buffer layer 120 may include an inorganic insulating material such as silicon oxide (SiO_{X}), silicon nitride (SiN_{X}), or silicon oxynitride (SiO_{X}N_{Y}) and may have a single or multi-layer structure including the above material.

The pixel circuit PC may be located on (e.g., disposed directly thereon) the buffer layer 120. As described above, in an embodiment the pixel circuit PC may include the first transistor T1, the second transistor T2, and the storage capacitor Cst. For convenience of illustration, the storage capacitor Cst is not shown in FIG. 3.

In an embodiment, the first transistor T1 may include a first semiconductor layer A1, a first gate electrode G1, a 1-1 connection electrode S1, and a 1-2 connection electrode D1, as shown in FIG. 3. For example, in an embodiment the 1-1 connection electrode S1 may be a source electrode, and the 1-2 connection electrode D1 may be a drain electrode. Alternatively, according to a polarity of the first transistor T1, the 1-1 connection electrode S1 may be a drain electrode, and the 1-2 connection electrode D1 may be a source electrode. As shown in FIG. 3, in an embodiment the second transistor T2 may include a second semiconductor layer A2, a second gate electrode G2, a 2-1 connection electrode S2, and a 2-2 connection electrode D2. For example, in an embodiment the 2-1 connection electrode S2 may be a source electrode, and the 2-2 connection electrode D2 may be a drain electrode. Alternatively, according to a polarity of the second transistor T2, the 2-1 connection electrode S2 may be a drain electrode, and the 2-2 connection electrode D2 may be a source electrode.

The first semiconductor layer A1 and the second semiconductor layer A2 may be located on (e.g., disposed on) the substrate 100. For example, in an embodiment the first semiconductor layer A1 and the second semiconductor layer A2 may be located on (e.g., disposed directly thereon in the z direction) the buffer layer 120. For example, the buffer layer 120 may be located between the substrate 100 and the first semiconductor layer A1 (e.g., directly therebetween in the z direction) and between the substrate 100 and the second semiconductor layer A2 (e.g., directly therebetween in the z direction). In an embodiment, the first semiconductor layer A1 may include a 1-1 semiconductor layer A11, a 1-2 semiconductor layer A12, and a 1-3 semiconductor layer A13. The 1-1 semiconductor layer A11 and the 1-2 semiconductor layer A12 may be spaced apart from each other and may be located on the buffer layer 120 (e.g., disposed directly thereon in the z direction). The 1-3 semiconductor layer A13 may be located between the 1-1 semiconductor layer A11 and the 1-2 semiconductor layer A12. For example, the 1-1 semiconductor layer A11 and the 1-2 semiconductor layer A12 may be spaced apart from each other in a horizontal direction parallel to an upper surface of the substrate 100, such as the x direction, with the 1-3 semiconductor layer A13 therebetween.

A first portion of the 1-3 semiconductor layer A13 may cover (e.g., directly contact) a portion of the 1-1 semiconductor layer A11, and a second portion of the 1-3 semiconductor layer A13 may cover (e.g., directly contact) a portion of the 1-2 semiconductor layer A12. A third portion of the 1-3 semiconductor layer A13 which is a portion of the 1-3 semiconductor layer A13 not covering (e.g., not directly contacting) the 1-1 semiconductor layer A11 or the 1-2 semiconductor layer A12, may directly contact the buffer layer 120. For example, in an embodiment the first and second portions of the 1-3 semiconductor layer A13 may be opposite lateral sides thereof (e.g., in the x direction) and the third portion of the 1-3 semiconductor layer A13 may be a central portion thereof (e.g., in the x direction). For example, the 1-1 semiconductor layer A11 may be connected to (e.g., directly connected thereto) the 1-2 semiconductor layer A12 by the 1-3 semiconductor layer A13. In an embodiment, the 1-1 semiconductor layer A11 may be electrically connected to the 1-2 semiconductor layer A12 by the 1-3 semiconductor layer A13.

In an embodiment, the second semiconductor layer A2 may include a 2-1 semiconductor layer A21 and a 2-2 semiconductor layer A22. The 2-1 semiconductor layer A21 may be located on (e.g., disposed on) the substrate 100, and the 2-2 semiconductor layer A22 may be located on (e.g., disposed on) the 2-1 semiconductor layer A21. For example, in an embodiment, the 2-2 semiconductor layer A22 may be disposed directly on an upper surface of the 2-1 semiconductor layer A21 in the z direction. For example, the 2-2 semiconductor layer A22 may cover a portion of the 2-1 semiconductor layer A21. For example, the area of the 2-2 semiconductor layer A22 (e.g., in a plan view) is less than the area of the 2-1 semiconductor layer A21 (e.g., in a plan view). Accordingly, a first portion of the 2-1 semiconductor layer A21 may be covered by the 2-2 semiconductor layer A22, and a second portion of the 2-1 semiconductor layer A21 may not be covered by the 2-2 semiconductor layer A22. For example, the 2-2 semiconductor layer A22 may be located on (e.g., disposed directly thereon in the z direction) a first portion of the 2-1 semiconductor layer A21, and the 2-2 semiconductor layer A22 may not be located on (e.g., disposed on in the z direction) a second portion of the 2-1 semiconductor layer A21. In an embodiment, the first portion of the 2-1 semiconductor layer A21 may be a central portion thereof (e.g., in the x direction) and the second portion of the 2-1 semiconductor layer A21 may be lateral sides thereof (e.g., in the x direction).

In an embodiment, the 1-1 semiconductor layer A11, the 1-2 semiconductor layer A12, and the 2-1 semiconductor layer A21 may include the same material as each other, and the 1-3 semiconductor layer A13 and the 2-2 semiconductor layer A22 may include (e.g., be composed of) the same material as each other. For example, the 1-3 semiconductor layer A13 may include a material different from that of the 1-1 semiconductor layer A11 and the 1-2 semiconductor layer A12, and the 2-2 semiconductor layer A22 may include (e.g., be composed of) a material different from that of the 2-1 semiconductor layer A21. In an embodiment, the 1-1 semiconductor layer A11, the 1-2 semiconductor layer A12, and the 2-1 semiconductor layer A21 may include a first oxide, and the 1-3 semiconductor layer A13 and the 2-2 semiconductor layer A22 may include a second oxide. A charge mobility of the first oxide may be higher than a charge mobility of the second oxide. For example, a carrier concentration of the first oxide may be higher than a carrier concentration of the second oxide. For example, carriers may be electrons, and an electron concentration of the first oxide may be higher than an electron concentration of the second oxide.

Thus, in an embodiment the 1-1 semiconductor layer A11 and the 1-2 semiconductor layer A12 may include a material having a higher charge mobility than a charge mobility of a material included in the 1-3 semiconductor layer A13. The 2-1 semiconductor layer A21 may include a material having a higher charge mobility than a charge mobility of a material included in the 2-2 semiconductor layer A22. For example, in an embodiment the first oxide may include indium tin oxide (ITO), and the second oxide may include indium gallium zinc oxide (IGZO).

Accordingly, the 1-3 semiconductor layer A13 including the second oxide having a low charge mobility may be located between the 1-1 semiconductor layer A11 and the 1-2 semiconductor layer A12 respectively connected to connection electrodes. A bilayer structure including a portion of the 2-1 semiconductor layer A21 including the first oxide having a high charge mobility and the 2-2 semiconductor layer A22 including the second oxide having a low charge mobility may be located between portions of the 2-1 semiconductor layer A21 respectively connected to connection electrodes. This bilayer structure may have a charge mobility similar to a charge mobility of the first oxide. Accordingly, the second semiconductor layer A2 of the second transistor T2 that is a switching transistor may have a higher charge mobility than a charge mobility of the first semiconductor layer A1 of the first transistor T1 that is a driving transistor.

A first inorganic insulating layer IIL1 may be located on (e.g., disposed directly thereon) the first semiconductor layer A1 and the second semiconductor layer A2. For example, in an embodiment the first inorganic insulating layer IIL1 may be formed over the entire surface of the substrate to cover the first semiconductor layer A1 and the second semiconductor layer A2. The first inorganic insulating layer IIL1 may include an inorganic material. For example, in an embodiment the first inorganic insulating layer IIL1 may include an inorganic insulating material such as silicon oxide (SiO_{X}), silicon nitride (SiN_{X}), or silicon oxynitride (SiO_{X}N_{Y}) and may have a single or multi-layer structure including the above material.

The first gate electrode G1 and the second gate electrode G2 may be located on (e.g., disposed directly thereon in the z direction) the first inorganic insulating layer IIL1. For example, the first gate electrode G1 and the second gate electrode G2 may be respectively located on the first semiconductor layer A1 and the second semiconductor layer A2. In an embodiment, the first gate electrode G1 may be located on the first semiconductor layer A1 to overlap the 1-3 semiconductor layer A13 (e.g., in the z direction). The second gate electrode G2 may be located on the second semiconductor layer A2 to overlap the 2-2 semiconductor layer A22 (e.g., in the z direction). For example, to ensure insulation between semiconductor layers and gate electrodes, the first inorganic insulating layer IIL1 may be located between the first semiconductor layer A1 and the first gate electrode G1 (e.g., in the z direction) and between the second semiconductor layer A2 and the second gate electrode G2 (e.g., in the z direction).

The first gate electrode G1 and the second gate electrode G2 may include various conductive materials and may have various layer structures. For example, in an embodiment the first gate electrode G1 and the second gate electrode G2 may include a low-resistance conductive material such as molybdenum (Mo), aluminum (Al), copper (Cu), and/or titanium (Ti) and may have a single or multi-layer structure including the above material. For example, the first gate electrode G1 and the second gate electrode G2 may have a single-layer structure including Mo or a multi-layer structure including Mo/Al/Mo.

A second inorganic insulating layer IIL2 may be located on (e.g., disposed directly thereon in the z direction) the first gate electrode G1 and the second gate electrode G2. For example, in an embodiment the second inorganic insulating layer IIL2 may be formed over the entire surface of the substrate 100 to cover the first gate electrode G1 and the second gate electrode G2. The second inorganic insulating layer IIL2 may include an inorganic material. For example, in an embodiment the second inorganic insulating layer IIL2 may include an inorganic insulating material such as silicon oxide (SiO_{X}), silicon nitride (SiN_{X}), or silicon oxynitride (SiO_{X}N_{Y}) and may have a single or multi-layer structure including the above material.

The 1-1 connection electrode S1, the 1-2 connection electrode D1, the 2-1 connection electrode S2, and the 2-2 connection electrode D2 may be located on the second inorganic insulating layer IIL2 (e.g., disposed directly thereon in the z direction). For example, the 1-1 connection electrode S1, the 1-2 connection electrode D1, the 2-1 connection electrode S2, and the 2-2 connection electrode D2 may be disposed above the first gate electrode G1 and the second gate electrode G2. For example, the second inorganic insulating layer IIL2 may be located between the first gate electrode G1 and the 1-1 connection electrode S1 (e.g., in the z direction), between the first gate electrode G1 and the 1-2 connection electrode D1 (e.g., in the z direction), between the second gate electrode G2 and the 2-1 connection electrode S2 (e.g., in the z direction), and between the second gate electrode G2 and the 2-2 connection electrode D2 (e.g., in the z direction). In an embodiment, the 1-1 connection electrode S1, the 1-2 connection electrode D1, the 2-1 connection electrode S2, and the 2-2 connection electrode D2 may be connected to semiconductor layers through contact holes formed in the first inorganic insulating layer IIL1 and the second inorganic insulating layer IIL2.

For example, in an embodiment the 1-1 connection electrode S1 may be connected to (e.g., directly connected thereto) the 1-1 semiconductor layer A11 through contact holes formed in the first inorganic insulating layer IIL1 and the second inorganic insulating layer IIL2. The 1-2 connection electrode D1 may be connected to (e.g., directly connected thereto) the 1-2 semiconductor layer A12 through contact holes formed in the first inorganic insulating layer IIL1 and the second inorganic insulating layer IIL2. In an embodiment, the 1-1 connection electrode S1 may be electrically connected to the 1-1 semiconductor layer A11 through contact holes formed in the first inorganic insulating layer IIL1 and the second inorganic insulating layer IIL2. The 1-2 connection electrode D1 may be electrically connected to the 1-2 semiconductor layer A12 through contact holes formed in the first inorganic insulating layer IIL1 and the second inorganic insulating layer IIL2.

In an embodiment, the 2-1 connection electrode S2 may be connected to (e.g., directly connected thereto) the 2-1 semiconductor layer A21 through contact holes formed in the first inorganic insulating layer IIL1 and the second inorganic insulating layer IIL2. The 2-2 connection electrode D2 may be connected to (e.g., directly connected thereto) the 2-1 semiconductor layer A21 through contact holes formed in the first inorganic insulating layer IIL1 and the second inorganic insulating layer IIL2. In an embodiment, the 2-1 connection electrode S2 may be electrically connected to the 2-1 semiconductor layer A21 through contact holes formed in the first inorganic insulating layer IIL1 and the second inorganic insulating layer IIL2. The 2-2 connection electrode D2 may be electrically connected to the 2-1 semiconductor layer A21 through contact holes formed in the first inorganic insulating layer IIL1 and the second inorganic insulating layer IIL2.

In an embodiment, one of the 1-1 connection electrode S1 and the 1-2 connection electrode D1 may be electrically connected to the first shielding layer BL1. For example, as shown in FIG. 3, the 1-1 connection electrode S1 may be electrically connected to the first shielding layer BL1. The 1-1 connection electrode S1 may be connected to (e.g., directly connected to) the first shielding layer BL1 through contact holes formed in the first inorganic insulating layer IIL1, the second inorganic insulating layer IIL2 and the buffer layer 120. The first shielding layer BL1 may be a lower 1-1 connection electrode. However, embodiments of the present disclosure are not necessarily limited thereto.

The 1-3 semiconductor layer A13 may not contact (e.g., directly contact) the 1-1 connection electrode S1 and the 1-2 connection electrode D1, and the 2-2 semiconductor layer A22 may not contact (e.g., directly contact) the 2-1 connection electrode S2 and the 2-2 connection electrode D2. However, the 1-3 semiconductor layer A13 may be connected to the 1-1 connection electrode S1 by the 1-1 semiconductor layer A11, and the 1-3 semiconductor layer A13 may be connected to the 1-2 connection electrode D1 by the 1-2 semiconductor layer A12. The 2-2 semiconductor layer A22 may be connected to the 2-1 connection electrode S2 and the 2-2 connection electrode D2 by the 2-1 semiconductor layer A21. For example, in an embodiment the 1-3 semiconductor layer A13 may be electrically connected to the 1-1 connection electrode S1 by the 1-1 semiconductor layer A11, and the 1-3 semiconductor layer A13 may be electrically connected to the 1-2 connection electrode D1 by the 1-2 semiconductor layer A12. The 2-2 semiconductor layer A22 may be electrically connected to the 2-1 connection electrode S2 and the 2-2 connection electrode D2 by the 2-1 semiconductor layer A21.

In an embodiment, the 1-1 connection electrode S1, the 1-2 connection electrode D1, the 2-1 connection electrode S2, and the 2-2 connection electrode D2 may include a conductive material including molybdenum (Mo), aluminum (Al), copper (Cu), or titanium (Ti) and may have a single or multi-layer structure including the conductive material. In an embodiment, the 1-1 connection electrode S1, the 1-2 connection electrode D1, the 2-1 connection electrode S2, and the 2-2 connection electrode D2 may have a multi-layer structure including Ti/Al/Ti.

In general, a semiconductor layer includes a channel region, and a source region and a drain region located opposite to each other with the channel region therebetween. The source region and the drain region are connected to connection electrodes on the semiconductor layer. In the case of a semiconductor layer having a low charge mobility, a portion of the semiconductor layer is metallized by performing plasma treatment on the portion of the semiconductor layer. In detail, when “A is metallized” in the specification, it means that A including an oxide semiconductor has different electrical characteristics through plasma treatment. For example, it means that the resistance of A after plasma treatment is lower than the resistance of A before plasma treatment. In the case of a semiconductor layer including an oxide having a low charge mobility, a source region and a drain region may be portions of a metallized semiconductor layer.

For example, when an oxide semiconductor undergoes plasma treatment, the oxide semiconductor is reduced, and thus, oxygen defects contained in the oxide semiconductor may be induced and oxygen vacancies may increase. In the oxide semiconductor with increased oxygen vacancies, a carrier concentration may increase, and thus, a threshold voltage, which is a critical voltage for conducting electricity from among semiconductor characteristics, may move in a negative direction (e.g., be reduced). This may mean that the oxide semiconductor is metallized to conduct electricity well. For example, the resistance of the oxide semiconductor after plasma treatment may be lower than the resistance of the oxide semiconductor before plasma treatment.

Such metallization may be performed by, in a process of removing a portion of an inorganic insulating layer formed on a semiconductor layer, performing plasma treatment on a portion of the semiconductor layer located under the portion of the inorganic insulating layer which is removed. In this case, when another layer is deposited on the semiconductor layer, hydrogen may penetrate into a channel region of the semiconductor layer adjacent to the portion of the semiconductor layer where the inorganic insulating layer is removed, causing a threshold voltage to be out of a preset range. This is because the hydrogen penetrating into the channel region acts as a source for generating carriers.

In the case of a semiconductor layer including an oxide having a high charge mobility, the oxide having a high charge mobility is included, and thus, a portion of the semiconductor layer may not be metallized. However, when an inorganic insulating layer is deposited on the semiconductor layer including the oxide having a high charge mobility, a channel region of the semiconductor layer may be easily damaged by plasma, causing a threshold voltage to be out of a preset range.

However, in the display apparatus 1 according to an embodiment of the present disclosure, since portions of the first semiconductor layer A1 connected to connection electrodes of the first transistor T1, for example, the 1-1 semiconductor layer A11 and the 1-2 semiconductor layer A12, have a high charge mobility, a portion of the first semiconductor layer A1 may not be metallized. For example, a portion of an inorganic insulating layer formed on the first semiconductor layer A1 may not be removed. Accordingly, even when another layer is deposited on the semiconductor layer, hydrogen does not penetrate into a channel region of the semiconductor layer, thereby preventing a threshold voltage from being out of a preset range. Accordingly, the risk of defects of the display apparatus 1 occurring during a manufacturing process may be reduced.

Also, in the case of the display apparatus 1 of an embodiment of the present disclosure, a portion of the 2-1 semiconductor layer A21 (e.g., a central portion) between portions of the 2-1 semiconductor layer A21 connected to connection electrodes of the second transistor T2 may be covered by the 2-2 semiconductor layer A22. Accordingly, even when an inorganic insulating layer is deposited on the second semiconductor layer A2, a channel region of the second semiconductor layer A2 is not easily damaged by plasma, thereby preventing a threshold voltage from being out of a preset range. Thus, the risk of defects of the display apparatus 1 occurring during a manufacturing process may be reduced.

In an embodiment, the display apparatus 1 may further include a third connection electrode CE3 located on the second inorganic insulating layer IIL2 (e.g., disposed directly thereon in the z direction). In an embodiment, the third connection electrode CE3 may be connected to (e.g., directly connected thereto) the second shielding layer BL2 through contact holes formed in the buffer layer 120, the first inorganic insulating layer IIL1, and the second inorganic insulating layer IIL2. Accordingly, the second transistor T2 may be formed in a gate-sync structure. For example, a gate voltage may be applied to the second shielding layer BL2 located under the 2-1 semiconductor layer A21 of the second transistor T2.

An organic insulating layer OIL may be located on (e.g., disposed directly thereon) the 1-1 connection electrode S1, the 1-2 connection electrode D1, the 2-1 connection electrode S2, and the 2-2 connection electrode D2. In an embodiment, the organic insulating layer OIL is a planarization insulating layer and may have a substantially flat top surface. Accordingly, the organic insulating layer OIL may provide a flat top surface so that the pixel electrode 311 of the display element 310 is formed flat. The organic insulating layer OIL may include an organic insulating material. For example, in an embodiment the organic insulating layer OIL may include benzocyclobutene (BCB), polyimide, hexamethyldisiloxane (HMDSO), a general-purpose polymer such as polymethyl methacrylate (PMMA) or polystyrene (PS), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a blend thereof. The organic insulating layer OIL may have a single or multi-layer structure including the above material.

The display element 310 may be located on the organic insulating layer OIL (e.g., disposed directly thereon in the z direction). In an embodiment, the display element 310 may be an organic light-emitting diode including the pixel electrode 311, the counter electrode 313, and an emission layer 312 located between the pixel electrode 311 and the counter electrode 313 (e.g., in the z direction). As described above, the display element 310 may be electrically connected to the pixel circuit PC. When the display element 310 is electrically connected to the pixel circuit PC, it may mean that the pixel electrode 311 of the display element 310 is electrically connected to the pixel circuit PC. For example, in an embodiment the pixel electrode 311 may be electrically connected to the first transistor T1 by contacting (e.g., directly contacting) any one of the 1-1 connection electrode S1 and the 1-2 connection electrode D1 through a contact hole formed in the organic insulating layer OIL. Although the pixel electrode 311 directly contacts the 1-1 connection electrode S1 through a contact hole formed in the organic insulating layer OIL in an embodiment shown in FIG. 3, embodiments of the present disclosure are not necessarily limited thereto.

In an embodiment, the pixel electrode 311 may include a conductive oxide such as indium tin oxide (ITO), indium zinc oxide (IZO), zinc oxide (ZnO), indium oxide (In2O3), indium gallium oxide (IGO), or aluminum zinc oxide (AZO). However, embodiments of the present disclosure are not necessarily limited thereto. For example, in an embodiment, the pixel electrode 311 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In an embodiment, the pixel electrode 311 may further include a film formed of ITO, IZO, ZnO, or In203 over/under the reflective film. For example, the pixel electrode 311 may have a three-layer structure including ITO/Ag/ITO.

A pixel-defining film 320 may be located on the organic insulating layer OIL (e.g., disposed directly thereon in the z direction). The pixel-defining film 320 may cover an edge (e.g., lateral edges in the x direction) of the pixel electrode 311. The pixel-defining film 320 may include a pixel opening, and the pixel opening may overlap the pixel electrode 311, such as a central portion of the pixel electrode (e.g., in the x direction). The pixel opening may define an emission area of light emitted from the display element 310. In an embodiment, the pixel-defining film 320 may include an organic insulating material and/or an inorganic insulating material. In some embodiments, the pixel- defining film 320 may include a light-blocking material.

The emission layer 312 may be located on the pixel electrode 311 (e.g., in the z direction). In an embodiment, the emission layer 312 may include a low molecular weight material or a high molecular weight material and may emit red light, green light, or blue light. However, embodiments of the present disclosure are not necessarily limited thereto, and any organic light-emitting material capable of emitting light may be used for the emission layer 312 without limitation.

The counter electrode 313 may be located on the emission layer 312 (e.g., in the z direction). For example, in an embodiment the counter electrode 313 may be integrally formed in a plurality of display elements and may correspond to the plurality of pixel electrodes 311. In an embodiment, the counter electrode 313 may include a light-transmitting conductive layer formed of ITO, In₂O₃, or IZO and may include a semi-transmissive film including a metal such as Al or Ag. For example, the counter electrode 313 may be a semi-transmissive film including magnesium (Mg) or Ag.

In an embodiment, since the display element 310 may be easily damaged by external moisture, oxygen, or the like, an encapsulation layer may cover and protect the display element 310. In an embodiment, the encapsulation layer may include at least one inorganic encapsulation layer and at least one organic encapsulation layer. For example, in an embodiment the at least one inorganic encapsulation layer may include an inorganic insulating material such as silicon oxide (SiO_{X}), silicon nitride (SiN_{X}), or silicon oxynitride (SiO_{X}N_{Y}). The at least one organic encapsulation layer may include a polymer-based material. Examples of the polymer-based material may include an acrylic resin, an epoxy resin, polyimide, and polyethylene. For example, the at least one organic encapsulation layer may include acrylate. In an embodiment, the encapsulation layer may include a first inorganic encapsulation layer, an organic encapsulation layer, and a second inorganic encapsulation layer which are sequentially stacked.

Although the display apparatus 1 has been described, embodiments of the present disclosure are not necessarily limited thereto. A method of manufacturing the display apparatus 1 may also fall within the scope of the disclosure. A method of manufacturing the display apparatus 1 will now be described.

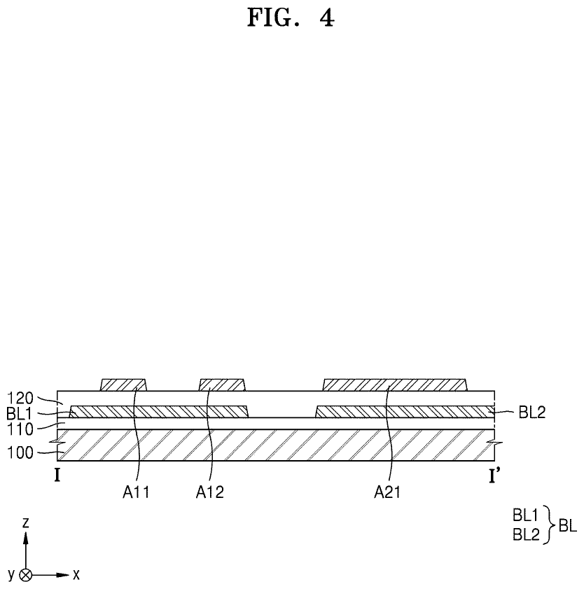

FIGS. 4 to 9 are cross-sectional views schematically illustrating part of a process of manufacturing the display apparatus 1 of FIG. 3. In detail, FIGS. 4 to 9 are cross-sectional views schematically illustrating a process of manufacturing the first transistor T1 and the second transistor T2 of the display apparatus 1 of FIG. 3. In FIGS. 4 to 9, for convenience of explanation, a method of manufacturing a display apparatus will be described based on a cross-section taken along line I-I′ of the display apparatus 1 of FIG. 1. When a method of manufacturing a display apparatus according to an embodiment is described with reference to FIGS. 4 to 9, the same members as those in FIGS. 1 to 3 are denoted by the same reference numerals and a repeated description thereof may be omitted for economy of description.

First, as shown in FIG. 4, the 1-1 semiconductor layer A11 and the 1-2 semiconductor layer A12 may be formed on the substrate 100. For example, in an embodiment, the 1-1 semiconductor layer A11 and the 1-2 semiconductor layer A12 may be formed on (e.g., formed directly thereon in the z direction) the buffer layer 120 located on the substrate 100. In an embodiment, the 1-1 semiconductor layer A11 and the 1-2 semiconductor layer A12 may be spaced apart from each other (e.g., in the x direction) and may be formed on the buffer layer 120 to overlap the first shielding layer BL1 (e.g., in the z direction).

The barrier layer 110, the shielding layer BL, and the buffer layer 120 may be located on the substrate 100. For example, in an embodiment the barrier layer 110 may be formed on the substrate 100 (e.g., formed directly thereon in the z direction). In an embodiment, the barrier layer 110 may be formed on an entire surface of the substrate 100 to cover the substrate 100. After the barrier layer 110 is formed, the shielding layer BL including the first shielding layer BL1 and the second shielding layer BL2 may be formed on the barrier layer 110 (e.g., formed directly thereon in the z direction). The first shielding layer BL1 and the second shielding layer BL2 may be formed on the barrier layer 110 to be spaced apart from each other (e.g., in the x direction). After the shielding layer BL is formed, the buffer layer 120 may be formed on (e.g., formed directly thereon) the shielding layer BL. The buffer layer 120 may be formed over the entire surface of the substrate 100 to cover the shielding layer BL.

The 1-1 semiconductor layer A11 and the 1-2 semiconductor layer A12 may be formed on the buffer layer 120 (e.g., formed directly thereon in the z direction). The 1-1 semiconductor layer A11 and the 1-2 semiconductor layer A12 may be spaced apart from each other (e.g., in the x direction) and may be formed on the buffer layer 120 to overlap the first shielding layer BL1 (e.g., in the z direction). The 1-1 semiconductor layer A11 and the 1-2 semiconductor layer A12 may include a first oxide. For example, the first oxide may include indium tin oxide (ITO).

In an embodiment, when the 1-1 semiconductor layer A11 and the 1-2 semiconductor layer A12 are formed, the 2-1 semiconductor layer A21 may also be formed on the substrate 100. For example, in an embodiment the 2-1 semiconductor layer A21 may be formed on the buffer layer 120 located on the substrate 100 (e.g., formed directly thereon in the z direction). The 2-1 semiconductor layer A21 may be spaced apart from the 1-1 semiconductor layer A11 and the 1-2 semiconductor layer A12 (e.g., in the x direction) and may be formed on the buffer layer 120 to overlap the second shielding layer BL2 (e.g., in the z direction). For example, in an embodiment the 1-1 semiconductor layer A11, the 1-2 semiconductor layer A12, and the 2-1 semiconductor layer A21 may be simultaneously formed by using the same material by forming a semiconductor layer including the first oxide on the buffer layer 120 and then patterning the semiconductor layer. Accordingly, the 2-1 semiconductor layer A21 may also include the first oxide.

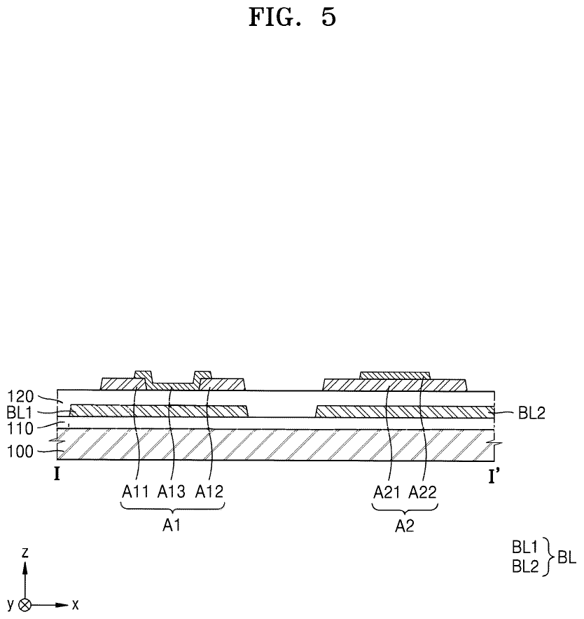

In an embodiment, as shown in FIG. 5, the 1-3 semiconductor layer A13 may then be formed between the 1-1 semiconductor layer A11 and the 1-2 semiconductor layer A12 (e.g., in the x direction). The 1-3 semiconductor layer A13 may be formed so that a first portion of the 1-3 semiconductor layer A13 covers a portion of the 1-1 semiconductor layer A11 and a second portion of the 1-3 semiconductor layer A13 covers a portion of the 1-2 semiconductor layer A12. In this embodiment, the 1-3 semiconductor layer A13 may be formed so that a third portion of the 1-3 semiconductor layer A13, that is, a portion of the 1-3 semiconductor layer A13 not covering the 1-1 semiconductor layer A11 or the 1-2 semiconductor layer A12, directly contacts the buffer layer 120. In an embodiment, the 1-3 semiconductor layer A13 may be formed so that the 1-1 semiconductor layer A11 is connected to the 1-2 semiconductor layer A12 by the 1-3 semiconductor layer A13. For example, the 1-3 semiconductor layer A13 may be formed so that the 1-1 semiconductor layer A11 is electrically connected to the 1-2 semiconductor layer A12 by the 1-3 semiconductor layer A13.

The 1-3 semiconductor layer A13 may include a material different from that of the 1-1 semiconductor layer A11 and the 1-2 semiconductor layer A12. For example, in an embodiment the 1-3 semiconductor layer A13 may include a second oxide. A charge mobility of the first oxide may be higher than a charge mobility of the second oxide. For example, the 1-1 semiconductor layer A11 and the 1-2 semiconductor layer A12 may include a material having a higher charge mobility than a charge mobility of a material included in the 1-3 semiconductor layer A13. For example, in an embodiment the second oxide may include indium gallium zinc oxide (IGZO).

In an embodiment when the 1-3 semiconductor layer A13 is formed, the 2-2 semiconductor layer A22 may also be formed on the 2-1 semiconductor layer A21. The 2-2 semiconductor layer A22 may be formed to cover a portion of the 2-1 semiconductor layer A21. For example, the area of the 2-2 semiconductor layer A22 (e.g., in a plan view) may be less than the area of the 2-1 semiconductor layer A21 (e.g., in a plan view). Accordingly, a first portion of the 2-1 semiconductor layer A21 may be covered by the 2-2 semiconductor layer A22, and a second portion of the 2-1 semiconductor layer A21 may not be covered by the 2-2 semiconductor layer A22. For example, the 2-2 semiconductor layer A22 may be formed so that the 2-2 semiconductor layer A22 is located on a first portion of the 2-1 semiconductor layer A21 and is not located on a second portion of the 2-1 semiconductor layer A21.

For example, in an embodiment the 1-3 semiconductor layer A13 and the 2-2 semiconductor layer A22 may be simultaneously formed by using the same material by forming a semiconductor layer including the second oxide on the 1-1 semiconductor layer A11, the 1-2 semiconductor layer A12, and the 2-1 semiconductor layer A21 and then patterning the semiconductor layer. Accordingly, the 2-2 semiconductor layer A22 may also include the second oxide. Thus, the 2-1 semiconductor layer A21 may include a material having a higher charge mobility than a charge mobility of a material included in the 2-2 semiconductor layer A22.

In an embodiment, the first oxide such as indium tin oxide (ITO) is crystalline and may be less etched by an etching solution than the second oxide such as indium gallium zinc oxide (IGZO). Accordingly, even when a semiconductor layer including the second oxide is formed on the 1-1 semiconductor layer A11, the 1-2 semiconductor layer A12, and the 2-1 semiconductor layer A21 and then is patterned, the 1-1 semiconductor layer A11, the 1-2 semiconductor layer A12, and the 2-1 semiconductor layer A21 may not be damaged.

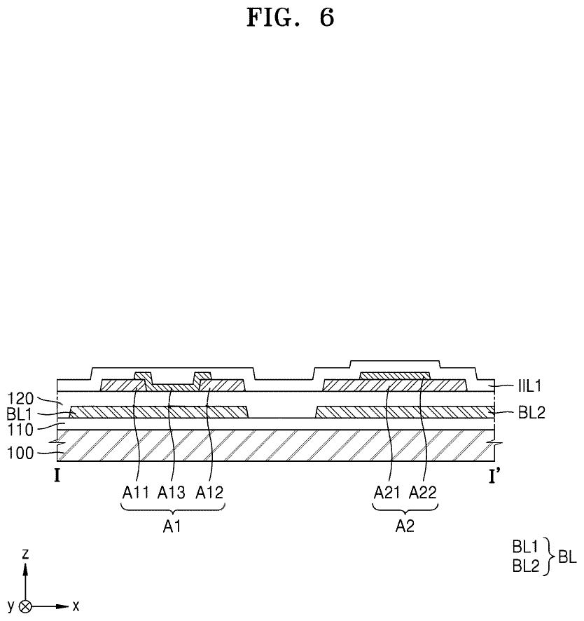

In an embodiment, as shown in FIG. 6, the first inorganic insulating layer IIL1 may then be formed on (e.g., formed directly thereon) the first semiconductor layer A1. For example, the first inorganic insulating layer IIL1 may be formed on the 1-1 semiconductor layer A11, the 1-2 semiconductor layer A12, and the 1-3 semiconductor layer A13. In an embodiment, the first inorganic insulating layer IIL1 may be formed over the entire surface of the substrate 100 to cover the first semiconductor layer A1 and the second semiconductor layer A2. For example, in an embodiment the first inorganic insulating layer IIL1 may include an inorganic insulating material such as silicon oxide (SiO_{X}), silicon nitride (SiN_{X}), or silicon oxynitride (SiO_{X}N_{Y}) and may have a single or multi-layer structure including the above material.

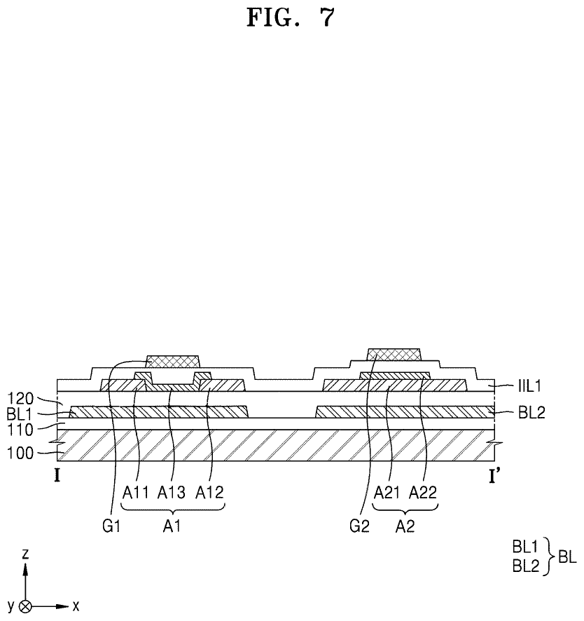

As shown in FIG. 7, the first gate electrode G1 may be formed on the first inorganic insulating layer IIL1. For example, in an embodiment the first gate electrode G1 may be formed on the first inorganic insulating layer IIL1 so that the first gate electrode G1 overlaps the 1-3 semiconductor layer A13 (e.g., in the z direction). In an embodiment, when the first gate electrode G1 is formed, the second gate electrode G2 may also be formed on the first inorganic insulating layer IIL1. For example, the second gate electrode G2 may be formed on the first inorganic insulating layer IIL1 to overlap the 2-2 semiconductor layer A22 (e.g., in the z direction). For example, in an embodiment the first gate electrode G1 and the second gate electrode G2 may be simultaneously formed by using the same material by forming a preliminary gate electrode layer on the first inorganic insulating layer IIL1 and then patterning the preliminary gate electrode layer.

The preliminary gate electrode layer may include any of various conductive materials and may have any of various layer structures. For example, in an embodiment the preliminary gate electrode layer may include a low-resistance conductive material such as molybdenum (Mo), aluminum (Al), copper (Cu), and/or titanium (Ti) and may have a single or multi-layer structure including the above material. For example, the preliminary gate electrode layer may have a single-layer including Mo or a multi-layer structure including Mo/Al/Mo.

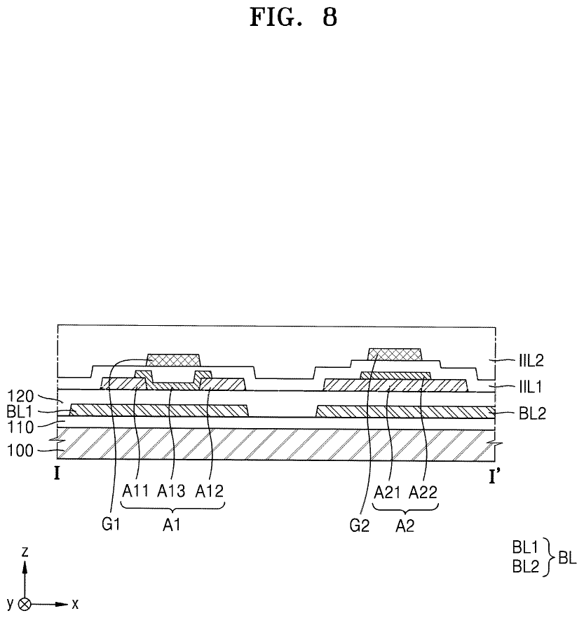

Next, as shown in FIG. 8, the second inorganic insulating layer IIL2 may be formed on the first gate electrode G1 (e.g., formed directly thereon). In an embodiment, the second inorganic insulating layer IIL2 may be formed over the entire surface of the substrate 100 to cover the first gate electrode G1 and the second gate electrode G2. For example, in an embodiment the second inorganic insulating layer IIL2 may include an inorganic insulating material such as silicon oxide (SiO_{X}), silicon nitride (SiN_{X}), or silicon oxynitride (SiO_{X}N_{Y}) and may have a single or multi-layer structure including the above material.

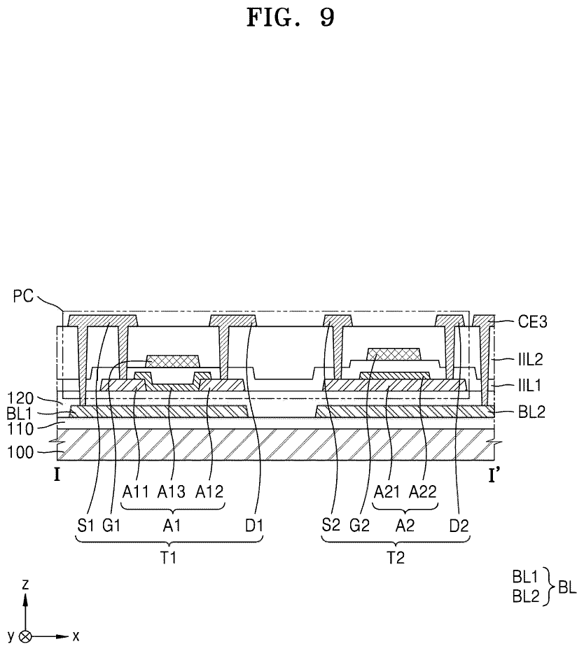

In an embodiment, as shown in FIG. 9, the 1-1 connection electrode S1 and the 1-2 connection electrode D1 may then be formed on the second inorganic insulating layer IIL2 (e.g., formed directly thereon in the z direction). For example, in an embodiment the 1-1 connection electrode S1 may be formed on the second inorganic insulating layer IIL2 so that the 1-1 connection electrode S1 is connected to (e.g., directly connected thereto) the 1-1 semiconductor layer A11 through contact holes formed in the first inorganic insulating layer IIL1 and the second inorganic insulating layer IIL2, and the 1-2 connection electrode D1 may be formed on the second inorganic insulating layer IIL2 so that the 1-2 connection electrode D1 is connected to (e.g., directly connected thereto) the 1-2 semiconductor layer A12 through contact holes formed in the first inorganic insulating layer IIL1 and the second inorganic insulating layer IIL2. Accordingly, the 1-1 connection electrode S1 may be electrically connected to the 1-1 semiconductor layer A11, and the 1-2 connection electrode D1 may be electrically connected to the 1-2 semiconductor layer A12.

In an embodiment, when the 1-1 connection electrode S1 and the 1-2 connection electrode D1 are formed, the 2-1 connection electrode S2 and the 2-2 connection electrode D2 may also be formed on the second inorganic insulating layer IIL2. For example, in an embodiment the 2-1 connection electrode S2 may be formed on the second inorganic insulating layer IIL2 so that the 2-1 connection electrode S2 is connected to (e.g., directly connected thereto) the 2-1 semiconductor layer A21 through contact holes formed in the first inorganic insulating layer IIL1 and the second inorganic insulating layer IIL2, and the 2-2 connection electrode D2 may be formed on the second inorganic insulating layer IIL2 so that the 2-2 connection electrode D2 is connected to (e.g., directly connected thereto) the 2-1 semiconductor layer A21 through contact holes formed in the first inorganic insulating layer IIL1 and the second inorganic insulating layer IIL2. Accordingly, the 2-1 connection electrode S2 and the 2-2 connection electrode D2 may be electrically connected to the 2-1 semiconductor layer A21.

For example, contact holes overlapping the 1-1 semiconductor layer A11, the 1-2 semiconductor layer A12, or the 2-1 semiconductor layer A21 may be formed in the first inorganic insulating layer IIL1 and the second inorganic insulating layer IIL2. In an embodiment, the 1-1 connection electrode S1, the 1-2 connection electrode D1, the 2-1 connection electrode S2, and the 2-2 connection electrode D2 may then be simultaneously formed by using the same material by forming a preliminary connection electrode layer on the second inorganic insulating layer IIL2 and patterning the preliminary connection electrode layer.

In an embodiment, the preliminary connection electrode layer may include a low-resistance conductive material such as molybdenum (Mo), aluminum (Al), copper (Cu), or titanium (Ti) and may have a single or multi-layer structure including the above material. In an embodiment, the preliminary connection electrode layer may have a multi-layer structure including Ti/Al/Ti. In an embodiment, contact holes overlapping the first shielding layer BL1 or the second shielding layer BL2 (e.g., in the z direction) may be formed in the buffer layer 120, the first inorganic insulating layer IIL1, and the second inorganic insulating layer IIL2, and when the 1-1 connection electrode S1 and the 1-2 connection electrode D1 are formed, the third connection electrode CE3 may be formed on the second inorganic insulating layer IIL2.

According to an embodiment as described above, a display apparatus capable of reducing the risk of defects occurring during a manufacturing process and a method of manufacturing the display apparatus may be implemented. However, the scope of embodiments of the present disclosure are not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope of the present disclosure.

What is claimed is:

1. A display apparatus comprising:
a pixel circuit disposed on a substrate, the pixel circuit comprising a first transistor and a second transistor; and
a display element electrically connected to the pixel circuit,
wherein the first transistor comprises:
a first semiconductor layer disposed on the substrate, the first semiconductor layer comprising a 1-1 semiconductor layer, a 1-2 semiconductor layer, and a 1-3 semiconductor layer disposed between the 1-1 semiconductor layer and the 1-2 semiconductor layer, wherein the 1-1 semiconductor layer and the 1-2 semiconductor layer include a same material as each other and the 1-3 semiconductor layer includes a material different from the material included in the 1-1 semiconductor layer and the 1-2 semiconductor layer;
a first gate electrode disposed on the first semiconductor layer, the first gate electrode overlaps the 1-3 semiconductor layer; and
a first connection electrode disposed on the first gate electrode, the first connection electrode is electrically connected to the 1-1 semiconductor layer or the 1-2 semiconductor layer.

2. The display apparatus of claim 1, wherein the second transistor comprises:
a second semiconductor layer comprising a 2-1 semiconductor layer disposed on the substrate and a 2-2 semiconductor layer disposed on the 2-1 semiconductor layer, the 2-2 semiconductor layer includes a material different from a material included in the 2-1 semiconductor layer;
a second gate electrode disposed on the second semiconductor layer, the second gate electrode overlaps the 2-2 semiconductor layer; and
a second connection electrode disposed on the second gate electrode, the second connection electrode is electrically connected to the 2-1 semiconductor layer.

3. The display apparatus of claim 2, further comprising:
a buffer layer disposed between the substrate and the first semiconductor layer and between the substrate and the second semiconductor layer;
a first inorganic insulating layer disposed between the first semiconductor layer and the first gate electrode and between the second semiconductor layer and the second gate electrode; and
a second inorganic insulating layer disposed between the first gate electrode and the first connection electrode and between the second gate electrode and the second connection electrode.

4. The display apparatus of claim 3, wherein the 1-3 semiconductor layer directly contacts the buffer layer.

5. The display apparatus of claim 4, wherein:
a first portion of the 1-3 semiconductor layer covers a portion of the 1-1 semiconductor layer; and
a second portion of the 1-3 semiconductor layer covers a portion of the 1-2 semiconductor layer.

6. The display apparatus of claim 5, wherein the 1-1 semiconductor layer is electrically connected to the 1-2 semiconductor layer by the 1-3 semiconductor layer.

7. The display apparatus of claim 4, wherein the 1-3 semiconductor layer is electrically connected to the first connection electrode by the 1-1 semiconductor layer or the 1-2 semiconductor layer.

8. The display apparatus of claim 3, wherein the 2-1 semiconductor layer is disposed between the 2-2 semiconductor layer and the buffer layer.

9. The display apparatus of claim 8, wherein the 2-2 semiconductor layer is electrically connected to the second connection electrode by the 2-1 semiconductor layer.

10. The display apparatus of claim 1, wherein the first transistor is electrically connected to the display element.

11. The display apparatus of claim 10, wherein:
the display element comprises a pixel electrode, a counter electrode, and an emission layer disposed between the pixel electrode and the counter electrode,
wherein the first connection electrode is electrically connected to the pixel electrode.

12. The display apparatus of claim 2, wherein the material included in the 1-1 semiconductor layer and the 1-2 semiconductor layer has a higher charge mobility than a charge mobility of the material included in the 1-3 semiconductor layer.

13. The display apparatus of claim 2, wherein the material included in the 2-1 semiconductor layer has a higher charge mobility than a charge mobility of the material included in the 2-2 semiconductor layer.

14. The display apparatus of claim 2, wherein:
the material included in the 1-1 semiconductor layer and the 1-2 semiconductor layer is a same material as the material included in the 2-1 semiconductor layer; and
the material included in the 1-3 semiconductor layer is a same material as the material included in the 2-2 semiconductor layer.

15. The display apparatus of claim 14, wherein:
the material included in the 1-1 semiconductor layer, the 1-2 semiconductor layer, and the 2-1 semiconductor layer comprises indium tin oxide; and
the material included in the 1-3 semiconductor layer and the 2-2 semiconductor layer comprises indium gallium zinc oxide.

16. A method of manufacturing a display apparatus, the method comprising:
forming a 1-1 semiconductor layer and a 1-2 semiconductor layer that are spaced apart from each other on a buffer layer disposed on a substrate, the 1-1 semiconductor layer and the 1-2 semiconductor layer include a same material as each other;
forming a 1-3 semiconductor layer between the 1-1 semiconductor layer and the 1-2 semiconductor layer, the 1-3 semiconductor layer includes a material different from the material of the 1-1 semiconductor layer and the 1-2 semiconductor layer;
forming a first inorganic insulating layer on the 1-1 semiconductor layer, the 1-2 semiconductor layer, and the 1-3 semiconductor layer;
forming a first gate electrode on the first inorganic insulating layer, the first gate electrode overlapping the 1-3 semiconductor layer;
forming a second inorganic insulating layer on the first gate electrode; and
forming a first connection electrode electrically connected to the 1-1 semiconductor layer or the 1-2 semiconductor layer on the second inorganic insulating layer.

17. The method of claim 16, wherein the forming of the 1-3 semiconductor layer comprises forming the 1-3 semiconductor layer in direct contact with the buffer layer.

18. The method of claim 17, wherein the forming of the 1-3 semiconductor layer comprises forming the 1-3 semiconductor layer so that a first portion of the 1-3 semiconductor layer covers a portion of the 1-1 semiconductor layer and a second portion of the 1-3 semiconductor layer covers a portion of the 1-2 semiconductor layer.

19. The method of claim 16, wherein the material included in the 1-1 semiconductor layer and the 1-2 semiconductor layer has a higher charge mobility than a charge mobility of the material included in the 1-3 semiconductor layer.

20. The method of claim 16, wherein:
the forming of the 1-1 semiconductor layer and the 1-2 semiconductor layer further includes forming a 2-1 semiconductor layer that is spaced apart from the 1-1 semiconductor layer and the 1-2 semiconductor layer on the buffer layer,
the forming of the 1-3 semiconductor layer further includes forming a 2-2 semiconductor layer on the 2-1 semiconductor layer,
the forming of the first gate electrode further includes forming a second gate electrode on the first inorganic insulating layer, the second gate electrode overlapping the 2-2 semiconductor layer, and
the forming of the first connection electrode on the second inorganic insulating layer further includes forming a second connection electrode electrically connected to the 2-1 semiconductor layer on the second inorganic insulating layer.

21. The method of claim 20, wherein the forming of the 2-2 semiconductor layer comprises forming the 2-2 semiconductor layer to cover a portion of the 2-1 semiconductor layer.

22. The method of claim 20, wherein the 2-1 semiconductor layer includes a material having a higher charge mobility than a charge mobility of a material included in the 2-2 semiconductor layer.

23. A display apparatus comprising:
a pixel circuit disposed on a substrate, the pixel circuit comprising a driving transistor and a switching transistor; and
a display element electrically connected to the pixel circuit,
wherein the driving transistor comprises a first semiconductor layer disposed on the substrate, the first semiconductor layer comprising a 1-1 semiconductor layer and a 1-2 semiconductor layer spaced apart from each other in a horizontal direction parallel to an upper surface of the substrate, and a 1-3 semiconductor layer disposed between the 1-1 semiconductor layer and the 1-2 semiconductor layer in the horizontal direction,
wherein the 1-3 semiconductor layer including a first lateral side directly contacting the 1-1 semiconductor layer, an opposite second lateral side directly contacting the 1-2 semiconductor layer and a central portion that does not directly contact either of the 1-1 semiconductor layer and the 1-2 semiconductor layer,
wherein the 1-1 semiconductor layer and the 1-2 semiconductor layer include a same material as each other and the 1-3 semiconductor layer includes a material different from the material included in the 1-1 semiconductor layer and the 1-2 semiconductor layer.

24. The display apparatus of claim 23, wherein the switching transistor comprises:
a second semiconductor layer comprising a 2-1 semiconductor layer disposed on the substrate;
a 2-2 semiconductor layer disposed directly on an upper surface of the 2-1 semiconductor layer, wherein the 2-2 semiconductor layer has a smaller area than the 2-1 semiconductor layer and overlaps a portion of the 2-1 semiconductor layer,
wherein the 2-2 semiconductor layer includes a material different from a material included in the 2-1 semiconductor layer.

25. The display apparatus of claim 24, wherein:
a material included in the 1-1 semiconductor layer, the 1-2 semiconductor layer and the 2-1 semiconductor layer is the same as each other;
a material included in the 1-3 semiconductor layer and the 2-2 semiconductor layer is the same as each other; and
the material included in the 1-1 semiconductor layer, the 1-2 semiconductor layer and the 2-1 semiconductor layer has a higher charge mobility than a charge mobility of the material included in the 1-3 semiconductor layer and the 2-2 semiconductor layer.
